(19) United States
(12) Patent Application Publication
(10) Pub. No.: US 2012/0187972 A1
(43) Pub. Date: Jul. 26, 2012

(54) WAFER LEVEL TESTING STRUCTURE

(75) Inventor: WEN-TSUNG LEE, New Taipei City (TW)

(73) Assignee: CHUNGHWA PRECISION TEST TECH. CO., LTD., TAOYUAN COUNTY (TW)

(21) Appl. No.: 13/244,528

(22) Filed: Sep. 25, 2011

(30) Foreign Application Priority Data
Jan. 24, 2011 (TW) 100201522

(51) Int. Cl. G01R 31/00

(52) U.S. Cl. 324/756.03

(57) ABSTRACT

A wafer level testing structure, disposed between a wafer and a prober, for transmitting the electrical signal of the wafer to the prober, the wafer level testing structure includes: a socket and a probe interface board disposed between the socket and the prober, wherein the probe interface board is electrically coupled to the prober, and a plurality of pogo pins is inserted through the socket, and one end of the plurality of pogo pins is electrically coupled to the wafer, the other end of the plurality of pogo pins is electrically coupled to the probe interface board, thereby the electrical signal of the wafer transmits from the probe interface board to the prober.

### BACKGROUND OF THE INVENTION

1. Field of the Invention

The present invention relates to a semiconductor probing structure; in particular, to a wafer level testing structure that can perform wafer acceptance test to a wafer.

2. Description of Related Art

During the process of forming semiconductor circuits or chips, no matter during which stage of formation, electrical probing for the acceptance of the semiconductor circuits or chips is necessary. Each semiconductor no matter in the wafer format or the packaged format must undergo acceptance test so as to ensure quality and electrical characteristics. As the production volume of semiconductor circuits keep increasing, the functionality of the semiconductor circuit are also getting more powerful, and corresponding structures becomes increasingly complex, therefore a high speed and accurate acceptance test is urgently in need.

Currently semiconductor acceptance test has the following two operations: (1) Chip Probing, CP operation; (2) Final Test, FT operation. However, each of the two acceptance testing structures has its own shortcoming. For the chip probing operation, the shortcoming is due to the fact that the connection interface between the bonding pad on the wafer and the probe PCB is a P7 probing pin, and the P7 probing pin are longer than other general probing pins, so that it is less suited for high-frequency-high-speed signal transmission. For the final test operation, the shortcoming is due to the fact that generally a socket is used to connect between the solder balls and the probe PCB for signal transmission, however because current ball grid array (BGA) have a loosely arranged interval (roughly □0.4 mm), so that in order to be suited for use by probe interface board of probe PCB that operates under 0.4 mm, formation process for the probe PCB needs to be modified.

Thereby, inventor of the present invention felt that there is available improvement for the aforementioned shortcomings, so painstakingly researched while applying operation theory, and so finally provides the present invention that is a reasonable and effective improvement for the aforementioned shortcomings.

### SUMMARY OF THE INVENTION

The object of the present invention is to provide a wafer level testing structure, which can shorten the path of the electrical signal transmission, so as to increase the transmission efficiency.

The other object of the present invention is to provide a wafer level testing structure, which can perform acceptance test over an entire wafer, so as to prevent the occurrence of stub effect caused by an excess of conducting body, due to the general via design.

In order to achieve the aforementioned objects, according to an embodiment of the present invention, a wafer level testing structure is provided, disposed between a wafer and a prober, for transmitting the electrical signal of the wafer to the prober, the wafer level testing structure includes: a socket, with a level surface and a plurality of pogo pins inserted through; and a probe interface board, disposed between the socket and the prober, electrically coupled to the plurality of pogo pins and the prober; wherein one end of the plurality of pogo pins is electrically coupled to the wafer, the other end of the plurality of pogo pins is electrically coupled to the probe interface board, so that the electrical signal of the wafer transmits from the probe interface board to the prober.

As described supra, the wafer level testing structure provided by the present invention has the following efficacy:
1. The present invention uses pogo pins, and due to the fact that pogo pins are shorter, so that not only is the path of transmission is shortened, but the transmission efficiency can be increased.
2. The wafer level testing structure of the present invention of the present invention can perform wafer acceptance test over the whole wafer, and not just a single packaged chip, therefore the probing/testing time is reduced.
3. The probe interface board of the present invention is formed using multiple times of pressing process, full impedance control and the design of through hole, blind via, and buried via, so as to prevent the occurrence of stub effect caused by an excess of conducting body, due to the general via design, which can additionally increase the transmission effect.

In order to further the understanding regarding the present invention, the following embodiments are provided along with illustrations to facilitate the disclosure of the present invention.

### BRIEF DESCRIPTION OF THE DRAWINGS

FIG. 1 shows a schematic diagram of a wafer level testing structure according to a first embodiment of the present invention;

FIG. 2 shows a schematic diagram of a wafer level testing structure according to a second embodiment of the present invention;

FIG. 3 shows a schematic diagram of a wafer level testing structure according to a third embodiment of the present invention;

FIG. 4 shows a schematic diagram of a wafer level testing structure according to a fourth embodiment of the present invention.

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended drawings.

### Implementation

### The First Embodiment

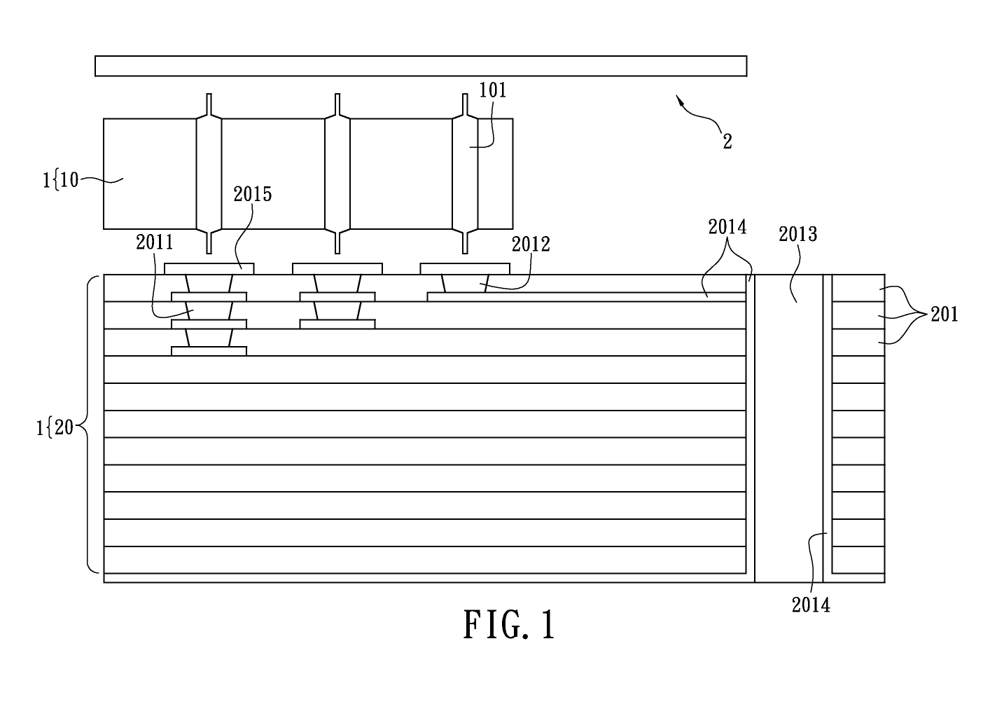

Reference FIG. 1, which shows a schematic diagram of a wafer level testing structure according to a first embodiment of the present invention. The present invention provides a wafer level testing structure 1, the wafer level testing structure 1 is disposed between a wafer 2 and a prober (not shown), for transmitting the electrical signal of the wafer 2 to the prober, wherein the wafer 2 is formed by wafer level package.

The wafer level testing structure 1 includes a socket 10 and a probe interface board 20. The socket 10 has a plurality of pogo pins 101 inserted through, and the surface of the socket 10 is level with no height difference, the two ends of the pogo pins 101 respectively projects out of the top surface and the bottom surface of the socket 10, and the top surface of the socket 10 faces the wafer 2, the bottom surface of the socket 10 faces the probe interface board 20. It should be noted, the length of the pogo pins 101 is shorter than the length of P7 probing pins, thereby the path of transmission is shortened, so that when the pogo pins 101 comes into contact with an object, evenness variance can be overcome, and the object will be in actual contact. Additionally, because the top surface of the socket 10 is level with no height difference, therefore the socket 10 is suitable for use of probing an entire wafer.

Probe interface board 20 is disposed between the socket 10 and the prober (not shown), wherein probe interface board 20 includes transmission circuit, and one side of the probe interface board 20 is electrically coupled to the plurality of pogo pins 101, and the other side of the probe interface board 20 is electrically coupled to the prober, thereby the electrical signal transmitted out of the pogo pins 101 can be transmitted to the prober through the transmission circuit of the probe interface board 20.

Furthermore, the probe interface board 20 is a probe PCB (probe printed circuit board) 201, and according to requirement, the probe interface board 20 can be formed with a plurality of probe PCB 201 using multiples times of pressing process or multi-layer process, and the probe PCBs 201 are mutually electrically coupled. The plurality of probe PCBs 201 are electrically coupled through disposed structures such as stacked via 2011, blind via 2012, through hole 2013, transmission line 2014, and probing pad 2015. It should be noted, the transmission circuit of the probe interface board 20 is formed through the aforementioned structures of stacked via 2011, blind via 2012, through hole 2013, transmission line 2014, and probing pad 2015.

As mentioned supra, multi-layer probe PCB formed through using multiple times of pressing process or multi-layer process constitute as conventional technique in the field of art, and utilizing structures such as blind via 2012, through hole 2013, transmission line 2014, and probing pad 2015 for the probe PCB 201 is also conventional technique for the field of art, therefore manufacturing process thereof will not be further described.

Also, because transmission circuit structure positions for stacked via 2011, blind via 2012, through hole 2013, transmission line 2014, and probing pad 2015 can be appropriately disposed within the printed circuit 201 according to design requirement, therefore through process of multiple times of pressing (unlike the traditional way of one time pressing) a plurality of probe PCBs (probe printed circuit boards) 201 or multi-layering a plurality of probe PCBs 201, the transmission circuit structures of the plurality of probe PCBs 201 can be aligned, so that the separation distance of the probing pad 2015 is decreased, such that the corresponding distance between the probing pad 2015 and the pogo pins 101 is also decreased, thereby the pogo pins of the present invention can be electrically coupled to circuits with smaller I/O distance. In other words, the application distance of the present invention probe interface board 20 can be □0.4 mm, with the more ideal application distance being □0.2 mm.

### The Second Embodiment

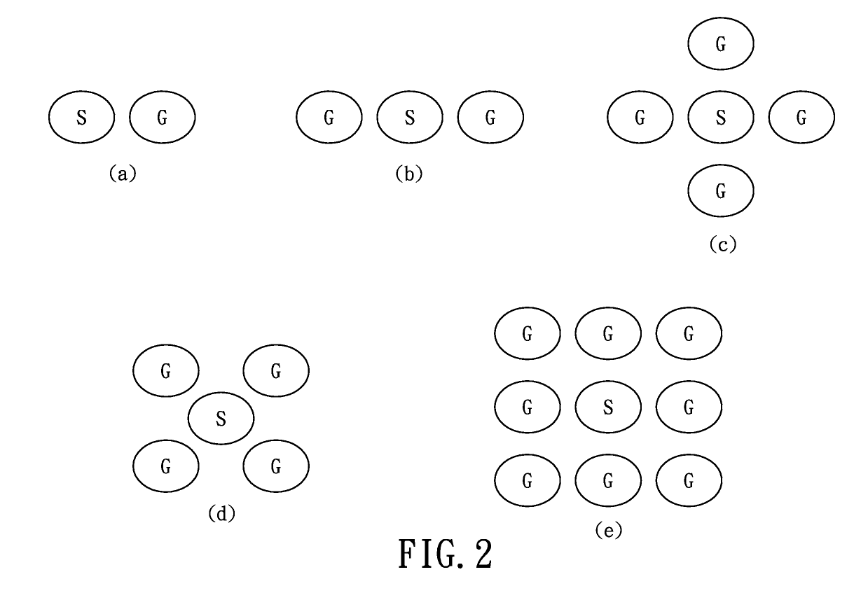

In order achieve impedance matching for the full transmission path so as to achieve the best transmission effect, probe interface board 20 can be formed by via impedance control design process, which means to dispose at least a grounding via G at the surroundings of through hole 2013, as shown in FIG. 2; and reference FIGS. 1 and 2 which shows the signal via S being the through hole 2013 of the present invention probe interface board 20, and the grounding via G is disposed at the signal via S surrounding.

It should be noted, the number of the grounding via G is not limited, and the array arrangement for the grounding via G is not necessary fixed, the actual number and array formation can be determined by design requirement, and a, b, c, d, e of FIG. 2 shows 5 array arrangement for the grounding via G.

### The Third Embodiment

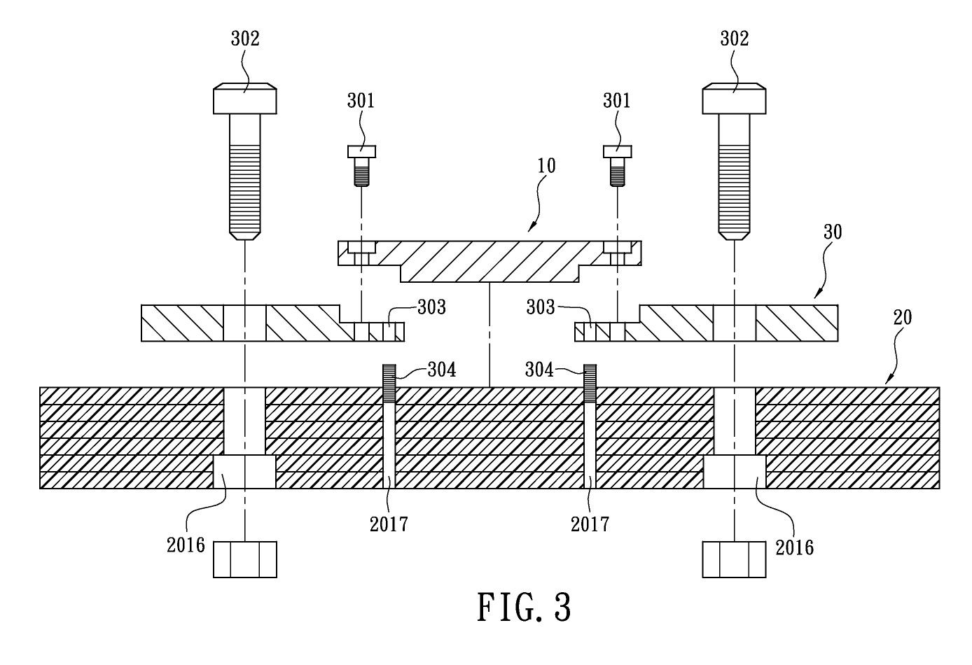

Reference FIG. 3, FIG. 3 further discloses an alignment method for the socket 10 and the probe interface board 20. As shown in FIG. 3, the wafer level testing structure 1 of the present invention further include a jig 30, the jig 30 is disposed between the socket 10 and the probe interface board 20, and the jig 30 can be made of metal material. The socket 10 is disposed on the jig 30, wherein the socket 10 and the jig 30 are fastened through at least one socket screw (or fasten screw) 301 connected there-between. Also, the probe interface board 20 further includes at least one screw nut 2016, at the location where the screw nut 2016 corresponds to the jig 30 is inserted with at least one jig screw 302, and the jig screw 302 fastens on the screw nut 2016, so that the jig 30 is thereby fixed on the probe interface board 20, and so the socket 10 is precisely aligned on the probe interface board 20. Due to the installation of the aforementioned jig 30, the jig can provide a firm support, and because the jig 30 is a metallic carrier, so that after the jig 30 has been machine drilled, there won't be an excessive difference that exceeds tolerance, so that the socket 10 that is disposed on the jig 30 can be precisely aligned on the probe interface board 20.

Additionally, besides using structures such as jig screw 302 and screw nut 2016 to connect and fasten between the probe interface board 20 and the jig 30, there can further more be at least a PCB guide-pin hole 2017 through the probe interface board 20, and at least one jig guide-pin hole 303 through the jig 30; the PCB guide-pin hole 2017 corresponds to the jig guide-pin hole 303, so that through using at least one guide pin 304 connecting the first and jig guide-pin hole 2017, 303, the jig 30 can be more precisely and firmly fixed on the probe interface board 20.

It should be noted, the aforementioned fasten screw 301, screw nut 2016, jig screw 302, PCB guide-pin hole 2017, jig guide-pin hole 303, and guide pin 304 are not fixed in number, the actual number can be determined according to design requirement, and can be one, two, three, or more. In FIG. 3, the fasten screw 301 and the jig screw 302 are screws, and the screw nut 2016 is a T-shaped hole.

### The Fourth Embodiment

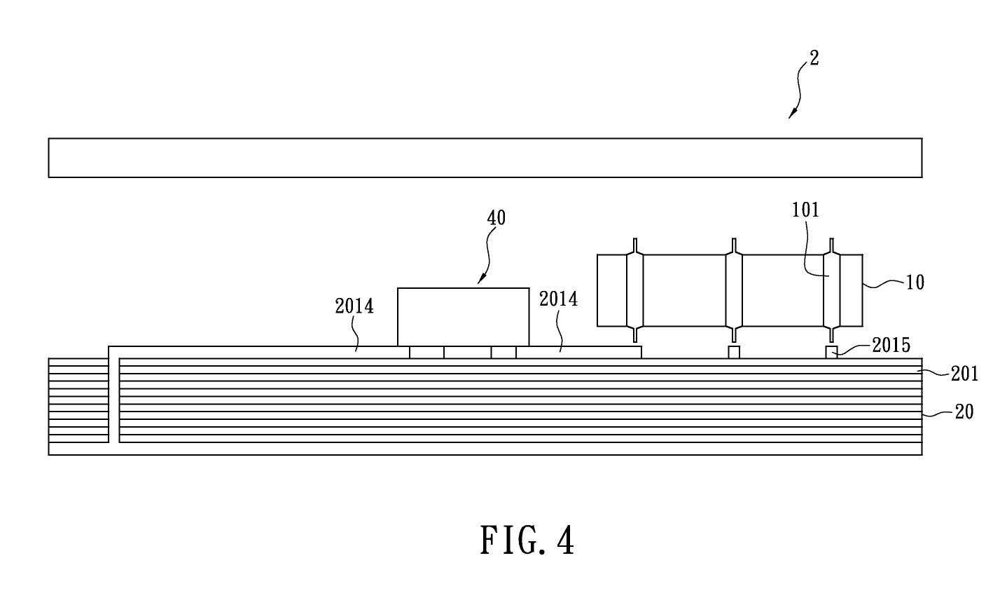

Reference FIG. 4, FIG. 4 shows a schematic diagram of a wafer level testing structure according to another embodiment. Considering that the wafer level packaged wafer 2 produces product that can be radio frequency (RF) related, and that RF products needs to undergo acceptance test, so the present invention further forms a radio frequency tuning circuit on the probe interface board 20, and the radio frequency tuning circuit is formed through many types of electronic components 40. In practice, these electronic components are resistors, capacitors, and/or inductors, so that by coordinating between these resistors, capacitors, and inductors the radio frequency tuning circuit can be designed, so that the wafer level testing structure 1 of the present invention can be utilized for acceptance testing of RF products.

As described supra, the wafer level testing structure of the present invention has the following efficacy:
1. The present invention uses pogo pins, and due to the fact that pogo pins are shorter, so that not only is the path of transmission is shortened, but the transmission efficiency can be increased.
2. The wafer level testing structure of the present invention of the present invention can perform wafer acceptance test over the whole wafer, and not just a single packaged chip, therefore the probing/testing time is reduced.
3. The probe interface board of the present invention is formed using multiple times of pressing process, full impedance control and the design of through hole, blind via, and buried via, so as to prevent the occurrence of stub effect caused by an excess of conducting body, due to the general via design, which can additionally increase the transmission effect.
4. The jig of the present invention can provide firm support, so that the socket that is disposed on the jig can be more precisely aligned with the probe interface board.
5. Because the probe interface board of the present invention has a radio frequency tuning circuit, so the wafer level testing structure of the present invention is suitable for testing RF products.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A wafer level testing structure for disposing between a wafer and a prober, for transmitting a diagnostic signal from the wafer to the prober, the wafer level testing structure comprising:
a socket having a plurality of pogo pins arranged thereon with each pin exposes respectively from the planar surfaces thereof; and
a probe interface board disposed between the socket and the prober for establishing electrical connection between the plurality of pogo pins and the prober;
wherein one end of each pogo pin is configured to establish electrical contact with the wafer, while the other end configured to establish electrical connection with the probe interface board, so as to transmit a diagnostic signal from the wafer through the probe interface board to the prober.

2. The wafer level testing structure according to claim 1, wherein the wafer is formed by wafer level package.

3. The wafer level testing structure according to claim 1, wherein the probe interface board has a radio frequency tuning circuit.

4. The wafer level testing structure according to claim 1, wherein the probe interface board is formed by via impedance control design process.

5. The wafer level testing structure according to claim 1, wherein the probe interface board is a probe PCB.

6. The wafer level testing structure according to claim 5, wherein the probe interface board is formed with a plurality of probe PCB using multiple times of pressing process or multi-layer process, and the plurality of probe PCB are mutually electrically coupled.

7. The wafer level testing structure according to claim 1, wherein the application distance of the probe interface board is □0.4 mm.

8. The wafer level testing structure according to claim 7, wherein a more ideal application distance of the probe interface board is □0.2 mm.

9. The wafer level testing structure according to claim 1, further comprises a positioning socket, the jig is disposed between the socket and the probe interface board, and the socket is disposed on the jig, wherein the socket and jig fastens through at least one fasten screw connected there-between.

10. The wafer level testing structure according to claim 9, wherein the probe interface board has at least one screw nut, and the jig is inserted with at least one jig screw, and the at least one jig screw fastens on the at least one screw nut, so that the jig is thereby fixed on the probe interface board.
